(19) United States
(12) Patent Application Publication
(10) Pub. No.: US 2008/0037229 A1
(43) Pub. Date: Feb. 14, 2008

(54) Electronic Module And Method For The Production Thereof

(75) Inventors: Markus Gradl, Regensburg (DE); Lothar Knopp, Berlin (DE); Rolf Steinegger, Regensburg (DE)

Correspondence Address: LERNER GREENBERG STEMER LLP, P O BOX 2480, HOLLYWOOD, FL, 33022-2480, US

(73) Assignee: BSH Bosch und Siemens Hausgerate GmbH

(21) Appl. No.: 10/590,371

(22) PCT Filed: Feb. 15, 2005
(86) PCT No.: PCT/EP05/50649

§ 371 Date: Dec. 28, 2006

(30) Foreign Application Priority Data
Feb. 23, 2004 (DE) 10 2004 008 738.5

(51) Int. Cl. H05K 1/00; H05K 3/30

(52) U.S. Cl. 361/748; 29/832

(57) ABSTRACT

An electronic module contains at least one circuit carrier coated on both sides with an electroconductive material and fitted with a first group of electronic components for forming a user interface and a second group of electronic components for forming a computing and control module. A method for producing such a module includes the step of carefully disposing the components respectively on the cover side and on the appliance side of the module in such a way that the configuration and function of the module can be completely unrelated. In order to reduce the production costs of the module, printed circuit boards coated on both sides are used as circuit carriers that are free of STH through-connection points. Accordingly, the signal transmission is carried out via plug-in elements, lateral elements, and through-connection elements.

The present invention relates to an electronic module comprising at least one circuit carrier coated on both sides with an electroconductive material and fitted with a first group of electronic components for forming a user interface and a second group of electronic components for forming a computing and control module; the invention further relates to a method for producing one such module.

Electronic components of the type specified initially and corresponding methods for producing such a module are known from circuit board insertion technology. In this case, the choice of printed circuit board base material for fabricating the corresponding electronic module is extremely important since the base material used to a considerable extent determines the electrical, mechanical and high-frequency properties as well as the fabrication method to be used and the expected costs of the board or module to be fabricated. Consequently, the choice of the correct base material is extremely important.

In the case of domestic appliances equipped with printed circuit boards, such as washing machines, dishwashers, refrigerators/freezers and cookers, for example, a printed circuit board coated on both sides and fitted on both sides is not used for cost reasons because these would necessitate relatively expensive printed circuit boards with prepared through-contacts. For this reason, the relatively inexpensive CEM1 or CEM3 printed circuit boards coated on one side are usually used at the present time. Those printed circuit boards have their field of application in mass applications with requirements for improved mechanical and electrical properties, such as is the case in domestic appliances. Those printed circuit boards are stampable but are only through-connectable to a certain extent. The disadvantage of electronic modules disposed on a printed circuit board coated on one side however is in particular the limited scope for placement of the components forming the module and the restricted scope for disentanglement of connection possibilities.

In this context, the term “disentanglement of a connection possibility” means the property that an electronic assembly for controlling an appliance is designed such that certain functional areas of the assembly are arranged spatially separately from one another as modules in order to adapt the respective appliance as flexibly as possible to changes with regard to design improvements or functionalities of the appliance. In particular, in modern domestic appliances design-influenced product criteria are being re-evaluated and increasingly taken into account in the configuration. The further development of such an appliance in fact substantially only relates to the control panel, that is the interface between the appliance and the user, where the actual electronics of the appliance can usually remain unchanged in principle. This is because the design of the control panel is playing an increasingly important role in the design of domestic appliances since this is increasingly being taken into account by the end customer in the decision to purchase. It has been found that in appliances fitted with printed circuit boards on which the relevant electronic module is provided in a so-called interwoven state, i.e. wherein the electronics are in a direct functional relationship to the user interface, for example, when making a modification to the control panel of the device it is frequently necessary to modify the electronics accordingly. This naturally has undesirable additional costs as a consequence.

A solution is known from DE 198 164 445 A1 where the electronic modules of an electrical appliance are applied and connected on respectively one circuit carrier coated on one side, wherein after loading the respective circuit carriers, the respectively unloaded surfaces of the individual circuit carriers are placed one upon the other and suitably fixed mechanically. The disadvantage of this method for producing such a module known from the prior art is that the mechanically connected and superimposed single boards are ultimately too thick and moreover, the method is relatively cost-intensive.

It is technical object of the present invention to provide an electronic module of the type specified initially and a corresponding method for producing such a module wherein it is possible to disentangle connection possibilities of the corresponding modules.

This object is achieved in an electronic module of the type specified initially, whereby the first group of electronic components for forming the user interface or the user interface module is applied and connected on a first side of the circuit carrier and the second group of electronic components for forming the computing and control module is applied and connected on a second side of the circuit carrier opposite to the first side.

The technical problem forming the basis of the present invention is further achieved by a method for producing the module according to the invention by the following process steps according to the invention: loading the first side of the circuit carrier with a first group of electronic components for forming a user interface of the module; loading the second side of the circuit carrier with a second group of electronic components for forming a computing and control module; and setting up signal transmission and/or power supply connections between the first side and the second side.

The advantages of the invention in particular are that as a result of the electronic components for forming the user interface being disentangled from the electronic components for forming the computing and control module, the respective component groups or modules can be developed and adapted completely separately from one another. In particular, in domestic appliances, for example, a new design proposal for the user interface or control panel of the appliances can be implemented particularly cost-effectively and simply completely separately from the switching electronics. Consequently, existing electronics can be used for a further development of the appliance.

The advantages of using a circuit carrier coated on both sides or the advantages of loading the circuit carrier on both sides are moreover appreciable since this provides the possibility of accommodating the same electronic circuit on a substantially smaller module than is the case with a circuit carrier coated on both sides. Preferably used as possible circuit carrier base materials are CEM-1, CEM-3 or FR-4 material. As has already been indicated, these materials are distinguished by improved mechanical and electrical properties. FR-4 base material is further designed for higher temperatures and additionally exhibits increased resistance to tracking. Said materials are standard materials and known from printed circuit board technology. Naturally, however, other base materials can also be provided for printed circuit boards or circuit carriers.

The method according to the invention provides a possibility for a very effective method for producing the electronic module according to the invention, which is simple to achieve, for optimising the disentanglement of the individual component groups. In particular, it is provided to connect the first side of the circuit carrier loaded with the first group of electronic components to form the user interface to the second group of electronic components loaded on the second side of the circuit carried to form the computing and control module by means of signal transmission and/or power supply connections. It is thereby possible that the first group of electronic components can be developed and adapted completely separately from the second group of electronic components. It is furthermore feasible, possibly to achieve a new design proposal for the control panel of a domestic appliance, to use existing electronics where it is merely necessary to adapt the first group of electronic components in accordance with the desired modifications of the new design proposal whilst the second group of electronic components remains completely unchanged. By setting up the signal transmission and/or power supply connections between the first side and the second side of the circuit carrier so that they are suitably matched, it is thus possible to implement the new design proposals for the control panel particularly cost-effectively and simply.

Preferred further developments of the invention are specified with regard to the electronic module in dependent claims 2 to 9 and with regard to the production method in dependent claims 11 to 13.

Thus, it is preferably provided for the electronic module that the circuit carrier is free from through-connection points, in particular STH through-connection points (STH=Silver Through Hole), wherein at least one signal transmission device is provided for two-way transmission of control signals between the first group of electronic components on the first side of the circuit carrier and the second group of electronic components on the second side of the circuit carrier and/or for supplying the first side with electrical power via the second side or conversely. As a result of this further development of the electronic module, in particular a simple separation can be made between cover design and function on a printed circuit board. The term “cover design” includes all the control and display elements forming the variant on the front side of the circuit carrier whilst the term “function” is to be understood as the variant-independent function on the back of the circuit carrier.

In a particularly preferred further development of the last-mention embodiment of the electronic module according to the invention, it is provided that the signal transmission device comprises at least one plug-in element which is plugged at an edge region of the circuit carrier via opposite plug-in regions formed on the first and the second side of the circuit carrier and conjugate with one another. In order to supply signals from the first group of electronic components from the first circuit carrier side, also called “cover side” since it points towards the control panel of the appliance, to the second group of electronic component in the second circuit carrier sides, also called “appliance side”, the signals on the cover side are fed to an edge region and are brought to the cover side by means of a plug-in element, such as by means of an edge card connector. In this case, it is provided that the master microcontroller of the appliance is located on the appliance side, i.e. on the circuit carrier side pointing towards the interior of the appliance. In the arrangement or design of the respective plug-in regions of the circuit carrier, it is further feasible to provide a step-shaped offset recess at the respective edge regions of the circuit carrier. In this case, the plug-in elements can be adapted to the respective width of the recess so that the plug-in element can be secured against lateral displacement. It is furthermore feasible to execute the plug-in region at the edge region of the circuit carrier so that this can also be used in parallel for connecting other electronic modules per plug-in element or edge card connector with connected leads. It is thus possible to use the plug-in regions not only as interfaces between the first and the second side of the circuit carrier but also as interfaces of the entire circuit carrier to other circuit carriers. Naturally, other embodiments are also feasible here.

In a particularly preferred realisation of the electronic module it is provided that the signal transmission device comprises at least one conductor element, in particular a cable jumper, which electrically connects a first contact region on the first side of the circuit carrier to a second contact region on the second side of the circuit carrier. A signal transmission device of this type in the form of a conductor element can be used for example for supplying power to the respective component groups on the first or second side since the conductor element can be designed to be adapted to the corresponding conditions such as dielectric strength etc. in a manner which is easy to achieve. In this case, it is feasible for example that the second side of the circuit carrier is connected to a power supply via a plug-in element and is in turn connected to the first side of the circuit carrier via a plug-in element in order to ensure that power is supplied to the component groups or modules loaded on both sides.

It is particularly advantageous that the signal transmission device comprises at least one through-connection element which runs through a through-hole in the circuit carrier and electrically connects a first contact region on the first side of the circuit carrier to a second contact region on the second side of the circuit carrier. In this case, it is feasible that that through-hole in the circuit carrier is incorporated by stamping, drilling, laser drilling or by milling. With this particularly preferred realisation of the electronic module according to the invention, although the printed circuit board base material is known to be free from plated-through holes in advance for cost reasons, the known advantages from printed circuit board technology with regard to through-connection elements such as STH plated-through holes can still be achieved by individually replacing the missing through-connection points by through-connection elements. This is an especially cost-effective possibility for achieving advantageous plated-through holes.

It is particularly advantageously provided that the through-connection element is a plug-in element especially formed of sheet metal, which comprises a plane contact surface and a pin region, which is spring-connected to the contact surface by means of a spring section, wherein the contact surface abuts flush against the contact region of the circuit carrier, and wherein the pin region runs through the through hole when the plug-in element is inserted in the through hole as a through-connection element. The plane contact surface of the plug-in element is particularly preferably designed such that this can be brought into contact with the corresponding contact region of the circuit carrier in a manner which is particularly easy to achieve. The spring section which connects the contact surface to the pin region is used, among other things, to fix the plug-in element securely in the through hole before the element is fixedly connected and brought into contact with the corresponding regions of the circuit carrier by soldering for example. Naturally, other embodiments and configurations of the plug-in element are also feasible here. Thus, it is possible to construct the plug-in element from a material that is individually matched to the corresponding requirements. For example, it would be feasible to use an electrically conductive polymer as the base material for the plug-in element for example.

In order that SMD components (SMD=Surface Mounted Device) can be used on both sides and wired or THD components (THD=Through Hole Device) can be used on one side of the circuit carrier, the first group of electronic components are components mounted on an SMD region of the first side of the circuit carrier by means of SMD technology whereas the second group of electronic components are components mounted on an SMD region of the second side of the circuit carrier by means of SMD technology and also components mounted in a THD region of the second side of the circuit carrier by means of THD technology. In this case, it is provided that the THD region of the second side is different from the SMD region of the second side and the SMD region of the second side is a region corresponding to and opposite to the SMD region of the first side.

However, it would also be feasible here that the first group of electronic components are components mounted on an SMD region of the first side of the circuit carrier by means of SMD technology as well as components mounted on a THD region of the first side of the circuit carrier by means of THD technology, whereas the second group of electronic components are components mounted on an SMD region of the second side of the circuit carrier by means of SMD technology. In this case, it is provided that the THD region of the first side is different from the SMD region of the first side and the SMD region of the second side is a region corresponding to and opposite to the SMD region of the first side.

The corresponding soldering techniques in electronics production, especially THD technology for through-hole mounted components and SMD technology for surface-mounted components are known from the prior art and will not be explained in detail here.

As an advantageous further development of the production method according to the invention, it is provided in the process step of setting up signal transmission and/or power supply connections between the first side and the second side of the circuit carrier, that plug-in regions are formed which extend on an edge region in an opposed and mutually conjugate manner on the first side and the second side of the circuit carrier and plug-in elements are then plugged onto the oppositely constructed and mutually conjugate plug-in regions.

Especially preferably for setting up signal transmission connections, at least one contact region is formed on the first side of the circuit carrier and at least one contact region is formed on the second side of the circuit carrier, which are then connected by means of a conductor element, such as a cable jumper for example.

With regard to another particularly preferred embodiment of the method according to the invention, it is further provided to form at least one through hole in the circuit carrier, at least one contact region on the first side of the circuit carrier and at least one second contact region on the second side of the circuit carrier and to then insert a through-connection element into the at least one through hole to electrically connect the at least one first contact region to the at least one second contact region.

Further advantages and functionalities of the invention will become clear from the following description of the preferred embodiments with reference to the figures.

In the figures:

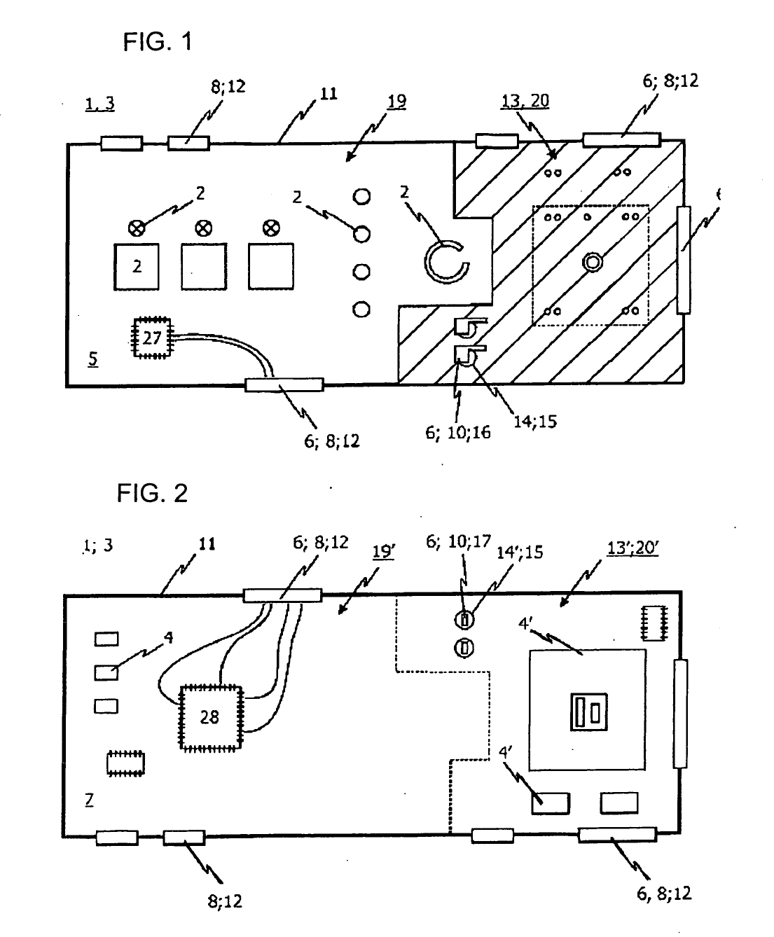

FIG. 1 shows the cover side of a first preferred embodiment of the electronic module according to the invention;

FIG. 2 shows the appliance side of the electronic module according to the invention according to the first embodiment, pertaining to the cover side shown in FIG. 1;

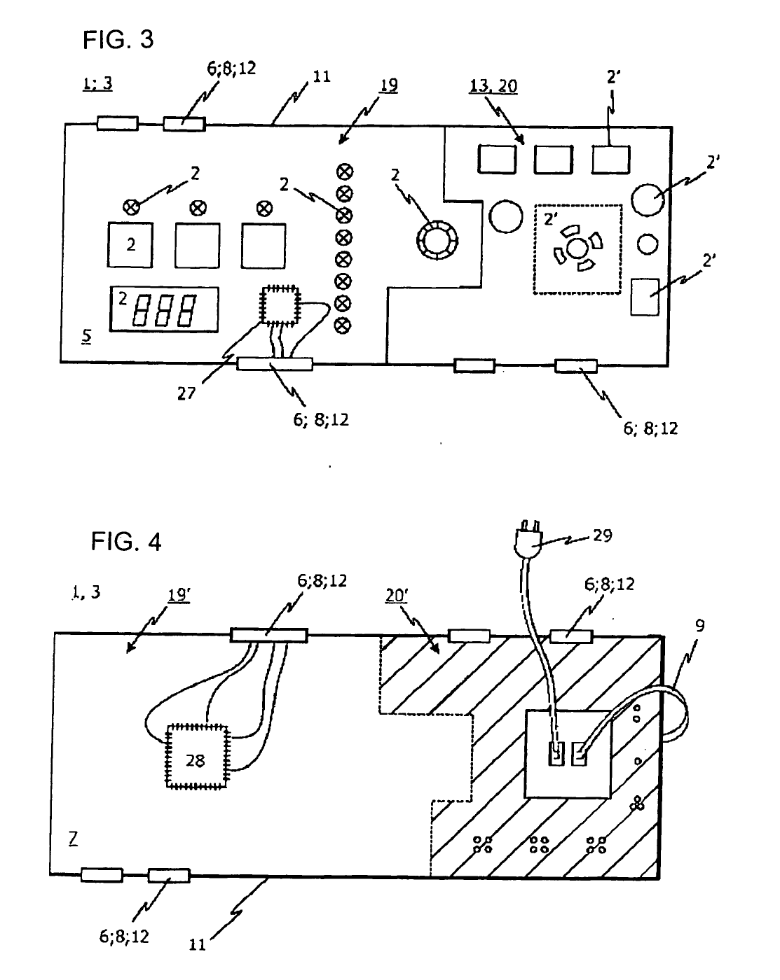

FIG. 3 shows the cover side of another preferred embodiment of the electronic module according to the invention;

FIG. 4 shows the appliance side pertaining to the cover side of the embodiment of the electronic module according to the invention shown in FIG. 3;

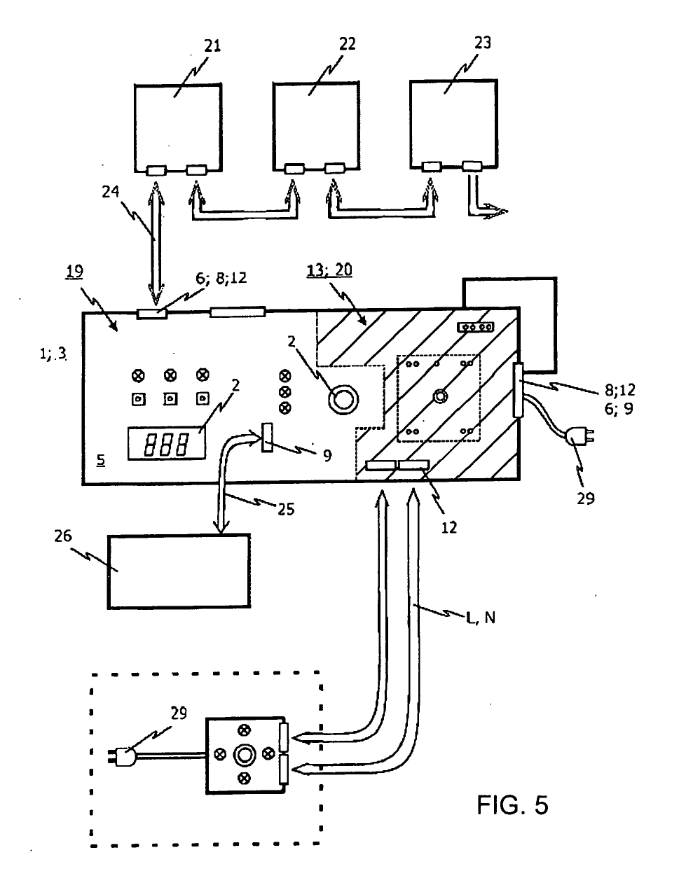

FIG. 5 is a schematic diagram of another embodiment of the electronic module according to the invention when installed;

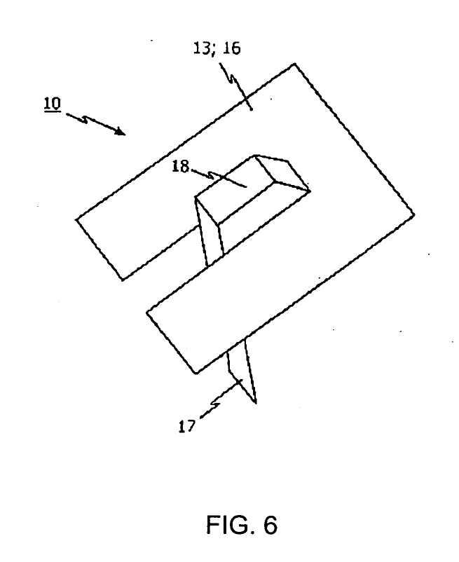

FIG. 6 is a three-dimensional diagram of an embodiment of the through-connection element according to the invention.

FIG. 1 shows the cover side 5 of a preferred embodiment of the electronic module 1. The embodiment shown here is a first variant of the module 1 where SMD components 2 are located on an SMD region 19 and the flow solder region 20 of the THD components 4′ inserted on the appliance side 7 is located on the cover side 5.

FIG. 2 shows the appliance side of the electronic module 1 according to the invention according to the first embodiment, pertaining to the cover side shown in FIG. 1. Both SMD components 4 and THD components 4′ are located on the appliance side, the THD components 4′ being located in a THD region 20′ of the appliance side 7 which is exactly opposite to the flow solder region 20 of the cover side 5. The SMD components 4 can be arranged on the appliance side 7 both on the THD region 20′ and on the SMD region 19′. The SMD region 19′ of the appliance side 7 is exactly opposite to the SMD region 19 of the cover side 5.

With reference to FIG. 1, a first group of electronic components 2 are mounted on the cover side 5 of the electronic module 1 in the SMD region 19 to form a user interface. This first group of electronic components 2 is made up, for example, of switches, push buttons, potentiometers, display elements, seven-segment display elements, light-emitting diodes and similar electronic components. These electronic components are all SMD components, i.e., components mounted on the surface 5 of the board using SMD technology known from the prior art. SMD technology usually comprises the process steps of dispensing, mounting and then connecting the components 2. These steps are known from the prior art and will not be explained in detail here.

As shown in FIG. 1, a microcontroller 27 is furthermore optionally arranged on the cover side 5 in the SMD region 19 of the module 1, this being provided to control or trigger the electronic components 2 of the first group likewise arranged on the cover side 5 for forming the user interface. In this connection, that microcontroller 27 should likewise be considered to be a component 2 of the first group since it primarily serves to form the user interface of the electronic module 1.

According to FIG. 2, both SMD components 4 and THD components 4′ are provided on the appliance side 7. The SMD components 4 are located on the SMD region 19′ which is positioned exactly opposite to the SMD region 19 of the cover side 5. Similarly, the THD components 4′ or the wired components 4′ are arranged on the appliance side 7 in the region 20′ which corresponds to and lies opposite to the SMD region 20 of the cover side 5. The components 4, 4′ arranged on the appliance side 7 belong to a second group of electronic components which serve to form a computing and control module of the electronic module 1. Those electronic components 4, 4′ of the second group are composed of the master microcontroller 28 and the relevant circuits or chips.

In the electronic module 1 according to the first embodiment, CEM-1, CEM-3 or SR-4 material is used as the base material of the circuit carrier. These materials are distinguished by improved mechanical and electrical properties. It is provided that the base materials are coated on both sides. In order to reduce the production costs of the electronic module 1, previously inserted through-connection points, especially STH through-connection points are intentionally not used in the printed circuit board base materials. Instead, signal transmission devices 6 are provided for two-way transmission of control signals between the components 2 of the cover side 5 and the components 4, 4′ of the appliance side 7. These signal transmission devices 6 are further used to supply electrical power to the electronic components of the cover side 5 via the appliance side 7 or conversely.

According to a first preferred embodiment of the electronic module 1 according to the invention shown in FIGS. 1 and 2, plug-in elements 8 and through-connection elements 10 are provided as signal transmission devices 6. The plug-in elements 8 are applied to the respective edge regions 11 of the circuit carrier 3. For this purpose, so-called plug-in regions 12 are formed at the respective positions of the edge region 11 of the circuit carrier 3. These plug-in elements 8 thus electrically connect the opposite, mutually conjugate plug-in regions 12 formed on the cover and the appliance side 5, 7. The plug-in regions 12 themselves are electrically connected via conductor tracks (not shown) to the respective components 2, 4, 4′; it is also feasible however, that the plug-in regions 12 are at least partly connected to the respective connections of the components 2, 4, 4′ by means of bonding wires or other wires.

In the first preferred embodiment of the electronic module 1 according to the invention, through-connection elements 10 are also provided as further signal transmission devices 6, each running through a first through hole 15 in the circuit carrier 3 and electrically connecting a first contact region 14 on the cover side 5 of the circuit carrier 3 to a second contact region 14′ on the appliance side 7 of the circuit carrier 3. At the same time, it is provided that the respective through holes 15 are incorporated in the circuit carrier 3 by stamping, drilling, laser drilling or by milling. It can also be seen in FIG. 1 that the first contact region 14 of the through-connection elements 10 falls in the flow region 20 of the cover side 5. The through-connection element 10 can thus be considered to be a THD component 4′ which is fixed and suitably connected by means of flow soldering, for example.

The first embodiment of the electronic module 1 according to the invention is distinguished in that only those electronic components 2 used to form the user interface of the module 1 are arranged on the cover side 5 whereas the components 4, 4′ for forming the computing and control module of the module 1 are provided on the appliance side 7. As a result, the electronic components 4, 4′ are completely disentangled. As a result of the arrangement of the components 2, 4, 4′ according to the first embodiment of the present invention, only the layout of the cover side 5 needs to be changed in the event of design changes or changes to the user interface. On the other hand, the layout of the appliance side 7 can remain unchanged which reduces the costs and the time expenditure incurred in connection with the change of design.

FIG. 3 shows the cover side 5 of a second preferred embodiment of the electronic module 1 according to the invention.

FIG. 4 shows the appliance side 7 pertaining to the cover side 5 of the electronic module 1 of the second embodiment according to the invention shown in FIG. 3.

The second preferred embodiment is distinguished from the first preferred embodiment according to FIGS. 1 and 2 in that both SMD components 2 and also wired or THD components 2′ are now located on the cover side. Thus, SMD components (not shown) and the flow solder region 20′ of the wired components 2′ of the cover side 5 are located on the corresponding appliance side 7.

By analogy with the first preferred embodiment of the electronic module 1, the components 2, 2′ used to configure the cover design are arranged exclusively on the cover side 5 whereas the components 4 used to configure the computing and control module are provided on the appliance side 7. For cost reasons the electronic module 1 according to the second embodiment is composed of a circuit carrier 3 coated on both sides with an electrically conductive material, the circuit carrier 3 being free from through-connection points, especially STH through-connection points. By analogy with the first embodiment, the lacking through-connection points are replaced by means of signal transmission devices 6 in the form of plug-in element 8 and mutually conjugate plug-in regions 12.

A difference of the second preferred embodiment with regard to the first preferred embodiment is further to be seen in that signal transmission devices 6 in the form of through-connection elements 10 are intentionally not used here, and instead conductor elements 9 such as cable jumpers are provided, which electrically connect a first contact region 13 on the cover side 5 of the circuit carrier 1 to a second contact region 13′ on the second side 7 of the circuit carrier 1. A conductor element 29 used to supply power to the electronic module is further provided on the appliance side 7.

A microcontroller 27 is also optionally provided on the cover side 5 of the second embodiment, this being used to trigger or to control the components 2, 2′ provided on the cover side 5 to form the user interface and is also considered as component 2, 2′ belonging to the first group.

FIG. 5 is a schematic diagram of another embodiment of the electronic module 1 according to the invention when installed. In the embodiment shown the view shows the cover side 5 of the electronic module 1. The electronic module 1 is embodied by analogy with the first preferred embodiment of FIGS. 1 and 2, i.e. SMD components 2 and the flow solder region 20 of the wired or THG components 4′ arranged on the appliance side 7 are located on the cover side 5. As shown, the electronic module 1 communicates via a plug-in element 8 embodied as an edge connector with a drive module 21 which is in turn connected to a sensor module 22 and an actuator module 23. Communication between the module 1 and the drive module 21 is made via a D bus 24 which is arranged on the edge connector or the plug-in element 8 on the electronic module 1.

An SPI D bus 25 connected to a display 26 is connected via a conductor element 9 on the cover side 5 of the electronic module 1. A power supply to the module 1 is also provided via a conductor element 9 which is arranged however in the flow solder region 20 of the cover side 5. It is optionally feasible to connect, for example, an external program selector module with light design to the electronic module 1 via one or more busses 24, 25, contact being made on the flow solder region 20 of the cover side 5 via conductor elements 9. An additional power supply for supplying power to the electronic module 1 can further be provided if required.

FIG. 6 is a three-dimensional view of an embodiment of the through-connection element 10 according to the invention. In the inserted state, the through-connection element 10 runs through a through hole 15 in the circuit carrier and connects a first contact region 14 on one side 5, 7 of the circuit carrier 3 to a second contact region 14′ on the second side of the circuit carrier 7, 5. In this case, for example, it is feasible that on the upper side of the through-connection element 10 corresponding to the contact surface 16, contact with the through-connection element 10 is made by reflow soldering whereas the underside or the pin region 17 of the through-connection element 10 is fixed by means of flow soldering or electrically connected to the respective contact regions 14, 14′.

The through-connection element 10 is a plug-in element especially made of sheet metal, comprising a flat contact surface 16 and a pin region 17 which is spring-connected to the contact surface 16 by means of a spring section 18, the contact surface 16 abutting flush on the contact region 14, 14′ of the circuit carrier 3 and the pin region 17 running through the through-hole 15 when the through-connection element 10 is inserted in the through hole 15.

The advantages of the electric module 1 according to the invention according to the preferred embodiments described above compared with known solutions are in particular the decoupling of design and function by the skilful arrangement of the components 2, 2′, 4, 4′ on respectively one side of a printed circuit board 5, 7, costs savings by eliminating a separate control module which contains the components relevant to the design solutions so far and savings in space by eliminating the separate control module.

### REFERENCE LIST

1 Electronic module
2 Electronic components of the first group (SMD components)
2′ Electronic components of the first group (THD components)
3 Circuit carrier
4 Electronic components of the second group (SMD components)
4′ Electronic components of the second group (THD components)
5 First side or cover side
6 Signal transmission device
7 Second side or appliance side
8 Plug-in element
9 Lateral element, conductor element
10 Through-connection element
11 Edge region
12 Plug-in region
13, 13′ Contact region
14, 14′ Contact region
15 Through hole
16 Contact surface
17 Pin region
18 Spring section
19, 19′ SMD region of first/second side
20, 20′ THD region of first/second side
21 Drive module
22 Sensor module
23 Actuator module
24 D bus
25 SPI-G bus
26 Display
27 Microcontroller
28 Master controller
29 Conductor element for power supply

1-13. (canceled)

14. An electronic module, comprising:
at least one circuit carrier having a first side, a second side opposite said first side, and an electroconductive material coating both said first and second sides;
a first group of electronic components for forming a user interface applied and connected onto said first side of said circuit carrier; and
a second group of electronic components for forming a computing and control module applied and connected onto said second side of said circuit carrier.

15. The electronic module according to claim 14, wherein said circuit carrier is free from through-connection points, including silver through hole through-connection points.

16. The electronic module according to claim 14, wherein said circuit carrier includes at least one signal transmission device for two-way transmission of control signals between said first group of electronic components on said first side of said circuit carrier and said second group of electronic components on said second side of said circuit carrier and/or for supplying said first side with electrical power via said second side or conversely.

17. The electronic module according to claim 16, wherein:
said circuit carrier has an edge region and plug-in regions on both said first and second sides;
said signal transmission device has at least one plug-in element plugging into said edge region of said circuit carrier via opposite said plug-in regions formed on said first and said second side of said circuit carrier and conjugate with one another.

18. The electronic module according to claim 16, wherein:
said first side of said circuit carrier has a first contact region;
said second side of said circuit carrier has a second contact region;
said signal transmission device has at least one conductor element electrically connecting said first contact region to said second contact region.

19. The electronic module according to claim 16, wherein:
said circuit carrier has a through-hole formed therein;
said first side of said circuit carrier has a first contact region;
said second side of said circuit carrier has a second contact region;
said signal transmission device has at least one through-connection element running through said through-hole in said circuit carrier and electrically connects said first contact region to said second contact region.

20. The electronic module according to claim 19, wherein said through-connection element is a plug-in element formed of sheet metal, said plug-in element having a spring section, a plane contact surface and a pin region spring-connected to said contact surface by said spring section, said contact surface abuts flush against at least one of said first and second contact regions of said circuit carrier, said pin region runs through said through-hole when said plug-in element is inserted in said through-hole as said through-connection element.

21. The electronic module according to claim 14, wherein:
said first side has a first SMD region;
said second side has a second SMD region and a THD region, said THD region is different from said second SMD region, said second SMD region is a region corresponding to and opposite to said first SMD region of said first side;
said first group of electronic components are mounted on said first SMD region by SMD technology; and
said second group of electronic components are mounted on said second SMD region by SMD technology and also in said THD region by THD technology.

22. The electronic module according to claim 14, wherein:
said first side has a first SMD region and a THD region being different from said first SMD region;
said second side has a second SMD region, said second SMD region is a region corresponding to and opposite to said first SMD region of said first side;
said first group of electronic components are mounted on said first SMD region by SMD technology and also mounted on said THD region by THD technology; and
said second group of electronic components are mounted on said second SMD region of said second side by SMD technology.

23. The electronic module according to claim 18, wherein said conductor element is a cable jumper.

24. A method for producing an electronic module, which comprises the steps of:
providing a circuit carrier;
loading a first side of the circuit carrier with a first group of electronic components for forming a user interface of the electronic module;
loading a second side of the circuit carrier with a second group of electronic components for forming a computing and control module; and
setting up signal transmission and/or power supply connections between the first side and the second side.

25. The method according to claim 24, wherein the setting up step further comprises:
forming plug-in regions extending on an edge region in an opposed and mutually conjugate manner on the first side and the second side of the circuit carrier; and
plugging a plug-in element onto the oppositely constructed and mutually conjugate plug-in regions.

26. The method according to claim 24, wherein the setting up step further comprises:
forming at least one first contact region on the first side of the circuit carrier and at least one second contact region on the second side of the circuit carrier; and
connecting the at least one first contact region to the at least one second contact region with a conductor element.

27. The method according to claim 24, wherein the setting up step further comprises:
forming at least one through hole in the circuit carrier;
forming at least one contact region on the first side of the circuit carrier and at least one second contact region on the second side of the circuit carrier; and
inserting a through-connection element into the at least one through hole to electrically connect the at least one first contact region to the at least one second contact region.
